(19) United States
(12) Patent Application Publication
(10) Pub. No.: US 2026/0282602 A1
(43) Pub. Date: Sep. 17, 2026

(54) METHOD OF MANUFACTURING CHIP-ON-WAFER FOR MICRO LED DISPLAY

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 19/166,861

(22) PCT Filed: Nov. 27, 2024
(86) PCT No.: PCT/KR2024/018937

§ 371 Date: Sep. 18, 2025

(30) Foreign Application Priority Data
Dec. 19, 2023 (KR) 10-2023-0185337

(51) Int. Cl. H10H 20/01

(52) U.S. Cl. CPC H10H 20/018; H10H 20/01335; H10H 20/017; H10H 20/019; H10H 20/032; H10H 20/0364

(57) ABSTRACT

The present invention relates to a method of manufacturing a chip-on-wafer for a micro LED display, the method, using a chip-on-wafer method to manufacture a lateral chip, a flip chip, and a vertical chip for a micro LED display, etching an undoped semiconductor region (uGaN) and an n-type semiconductor region (nGaN) of a semiconductor layer without damaging the chips to allow thickness of the semiconductor layer to be significantly reduced.

### TECHNICAL FIELD

The present invention relates to a method of manufacturing a chip-on-wafer for a micro light-emitting diode (LED) display, and more particularly, to a method of manufacturing a chip-on-wafer for a micro LED display, which can significantly reduce the thickness of a semiconductor layer by etching an un-doped semiconductor region (uGaN) and an n-type semiconductor region (nGaN) of the semiconductor layer without damaging a chip, in manufacturing lateral chips, flip chips, and vertical chips for a micro LED display using a chip-on-wafer method.

### BACKGROUND ART

Recently, as the demand for high-performance metaverse devices has increased, there has been a growing need for smaller-sized chips for the manufacture of micro-scale LED displays. In response to such market demands, micro LED display chips currently being manufactured have a thickness in the range of 5 μm to 8 μm, but achieving a thickness of less than 5 μm is considered difficult due to process-related difficulties and issues such as chip breakage.

Meanwhile, a chip-on-wafer method refers to a method in which the entire process, from the epitaxial growth of a semiconductor layer on an initial growth substrate to the final fabrication (fab) process, is performed on the initial growth wafer.

According to such a conventional chip-on-wafer method, since a stacked structure of the chip is completed using only the initial growth substrate, a thickness of an un-doped semiconductor region (e.g., uGaN) or an n-type semiconductor region (e.g., nGaN) cannot be adjusted. As a result, it is difficult to manufacture micro LEDs with a thickness of 5 μm or less, and the presence of such a thick un-doped semiconductor region (e.g., uGaN, uInGaN, uAlGaN, uAlGaInN, uGaP, uInGaP, uAlGaP, or uAlGaInP) leads to a reduction in light extraction efficiency.

Meanwhile, in the conventional chip-on-wafer method, the completed chip may be attached to a thin film transistor (TFT) glass, an interposer, or the like, and then the initial growth substrate on the opposite side may be removed to expose the un-doped semiconductor region (e.g., uGaN, uInGaN, uAlGaN, uAlGaInN, uGaP, uInGaP, uAlGaP, or uAlGaInP), but even when attempting to etch the exposed un-doped semiconductor region (e.g., uGaN, uInGaN, uAlGaN, uAlGaInN, uGaP, uInGaP, uAlGaP, or uAlGaInP), the completed chip, the TFT glass, or the interposer may be damaged due to high temperatures and injected gases generated during the etching process.

Furthermore, when the initial growth substrate is removed by a laser lift-off (LLO) process, numerous gallium (Ga) droplets (solid or powder) that interfere with the scattering of generated light are generated on the surface of the semiconductor layer from which the initial growth substrate has been removed. Currently, the gallium droplets are removed by hydrochloric acid treatment or taping, but the hydrochloric acid treatment may damage the TFT glass or the interposer, and when the taping is used, there is an issue that complete removal of the gallium (Ga) droplets is not possible. However, in the case of removing the initial growth substrate for micro LEDs using a chemical lift-off (CLO) process, such as Si (nitrides emitting blue, green, and red light) or GaAs (phosphides emitting red light), there is no issue related to the gallium droplets.

In addition, according to the conventional chip-on-wafer method, since the stacked structure of the chip is completed using only the initial growth substrate, an ohmic contact electrode is inevitably formed in a back-end process. In this case, the formation of the ohmic contact electrode essentially requires heat treatment at a temperature of 300° C. or higher, and thus there is an issue that the chip, in which a plurality of layers are already stacked, may be damaged by the high temperature.

### DISCLOSURE

### Technical Problem

The present invention is directed to solving the above-mentioned conventional problems and providing a method of manufacturing a chip-on-wafer for a micro light-emitting diode (LED) display, which can significantly reduce the thickness of a semiconductor layer by etching an un-doped semiconductor region (uGaN) and an n-type semiconductor region (nGaN) of the semiconductor layer without damaging a chip, in manufacturing lateral chips, flip chips, and vertical chips for a micro LED display using a chip-on-wafer method.

### Technical Solution

The above objective is achieved, according to the present invention, by a method of a method of manufacturing a chip-on-wafer for a micro light-emitting diode (LED) display, the method including a growth operation of epitaxially growing a semiconductor layer on an initial growth substrate, an electrode formation operation of forming an ohmic contact electrode on the semiconductor layer, an adhesion operation of bonding the ohmic contact electrode to an intermediate temporary substrate through an adhesive layer, an exposure operation of exposing one surface of the semiconductor layer by removing the initial growth substrate, an etching operation of etching the exposed one surface of the semiconductor layer to reduce a thickness of the semiconductor layer, a bonding operation of bonding the etched one surface of the semiconductor layer to a final support substrate, and a removal operation of removing the intermediate temporary substrate and the adhesive layer.

Further, in the growth operation, a third semiconductor region, a second semiconductor region, an active region, and a first semiconductor region may be epitaxially grown in sequence on the initial growth substrate, in the etching operation, the third semiconductor region, which is exposed, may be etched to reduce the thickness of the semiconductor layer, and the third semiconductor region may be an un-doped semiconductor region.

Further, in the etching operation, the second semiconductor region may be etched to reduce the thickness of the semiconductor layer, and the second semiconductor region may be an n-type semiconductor region.

The above objective is also achieved, according to the present invention, by a method of a method of manufacturing a chip-on-wafer for a micro light-emitting diode (LED) display, the method including a growth operation of epitaxially growing a semiconductor layer on an initial growth substrate, an electrode formation operation of forming an ohmic contact electrode on the semiconductor layer, a bonding operation of bonding the ohmic contact electrode to a final support substrate, an exposure operation of exposing one surface of the semiconductor layer by removing the initial growth substrate, and an etching operation of etching the exposed one surface of the semiconductor layer to reduce a thickness of the semiconductor layer.

Further, in the growth operation, a third semiconductor region, a second semiconductor region, an active region, and a first semiconductor region may be epitaxially grown in sequence on the initial growth substrate, in the etching operation, the third semiconductor region, which is exposed, may be etched to reduce the thickness of the semiconductor layer, and the third semiconductor region may be an un-doped semiconductor region.

Further, in the etching operation, the second semiconductor region may be etched to reduce the thickness of the semiconductor layer, and the second semiconductor region may be an n-type semiconductor region.

### Advantageous Effects

According to the present invention, the thickness of a semiconductor layer can be significantly reduced to a range of 0.57 μm to 5.7 μm by etching an un-doped semiconductor region (uGaN) and an n-type semiconductor region (nGaN) of the semiconductor layer without damaging a chip, thereby enabling the manufacture of high-quality and high-brightness chips for micro LED displays.

Further, according to the present invention, the issue of gallium (Ga) droplets remaining on a surface of a semiconductor layer can be fundamentally prevented, thereby significantly improving light extraction efficiency.

Meanwhile, the effects of the present invention are not limited to the above-mentioned effects, and various effects may be included within the scope which is apparent to those skilled in the art from contents to be described below.

### DESCRIPTION OF DRAWINGS

FIGS. 1 and 2 illustrate an overall process in which a chip-on-wafer is manufactured in accordance with a method of manufacturing a chip-on-wafer for a micro light-emitting diode (LED) display according to a first embodiment of the present invention.

FIG. 3 is a flowchart of a method of manufacturing a chip-on-wafer for a micro-LED display according to a first embodiment of the present invention.

FIG. 4 illustrates various structures of chip-on-wafers manufactured in accordance with the method of manufacturing a chip-on-wafer for a micro LED display according to the first embodiment of the present invention.

FIG. 5 illustrates an overall process in which a chip-on-wafer is manufactured in accordance with a method of manufacturing a chip-on-wafer for a micro LED display according to a second embodiment of the present invention.

FIG. 6 is a flowchart of the method of manufacturing a chip-on-wafer for a micro LED display according to the second embodiment of the present invention.

FIG. 7 illustrates various structures of chip-on-wafers manufactured in accordance with the method of manufacturing a chip-on-wafer for a micro LED display according to the second embodiment of the present invention.

FIG. 8 is a diagram for describing dimensional deviations that affect performance variations in the methods of manufacturing chip-on-wafers for micro LED displays according to the first and second embodiments of the present invention.

### MODES OF THE INVENTION

Hereinafter, some embodiments of the present invention will be described in detail with reference to exemplary drawings. It should be noted that in adding reference numerals to the components of each drawing, the same components have the same number when possible, even though the same components are shown in different drawings

In addition, in describing the embodiments of the present invention, when detailed descriptions of related known structures or functions may obscure the gist of the present invention, the detailed description thereof will be omitted.

In addition, terms such as first, second, A, B, (a), (b), and the like may be used herein to describe components of the embodiments of the present invention. Each of these terms is not used to define an essence, order, or sequence of a corresponding component but used merely to distinguish the corresponding component from other component(s).

Hereinafter, a method (S100) of manufacturing a chip-on-wafer for a micro-light-emitting diode (LED) display according to a first embodiment of the present invention will be described in detail with reference to the accompanying drawings.

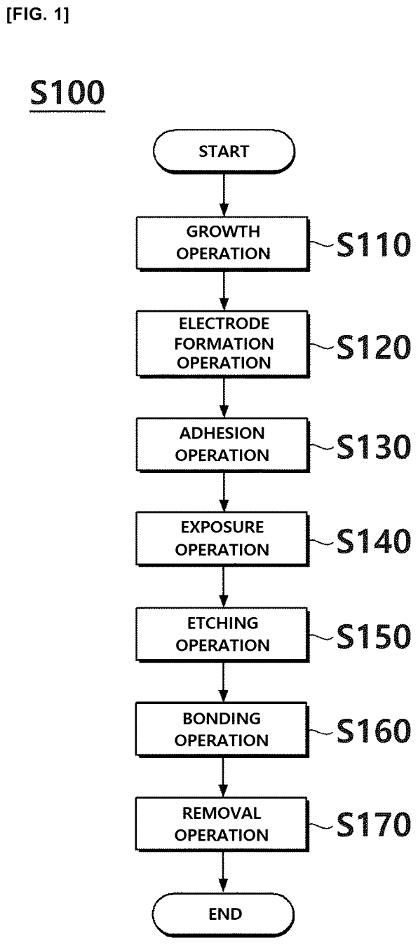

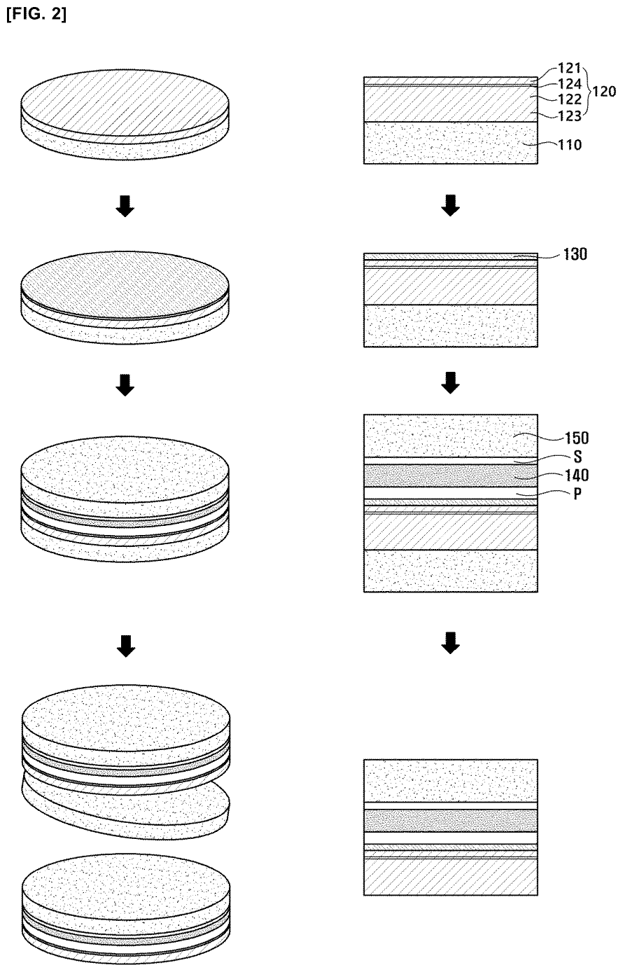

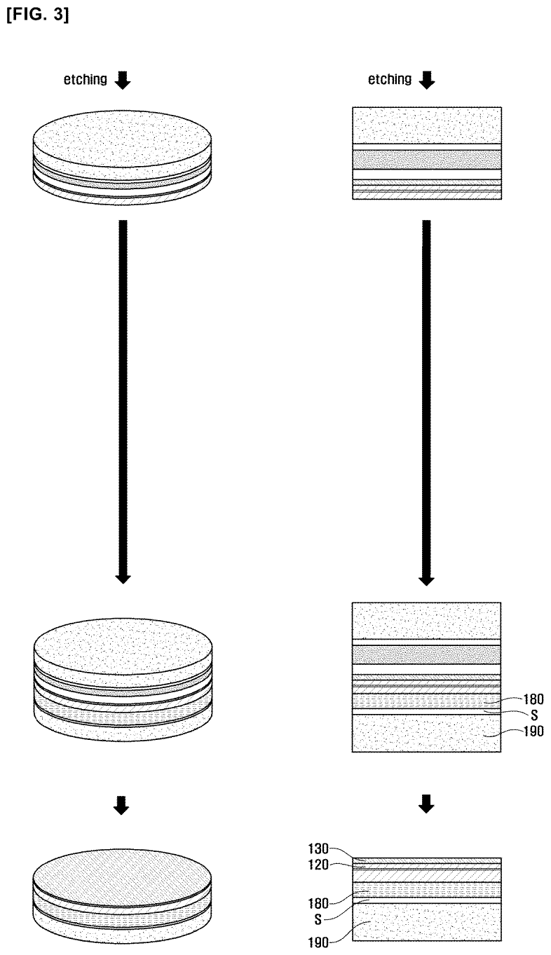

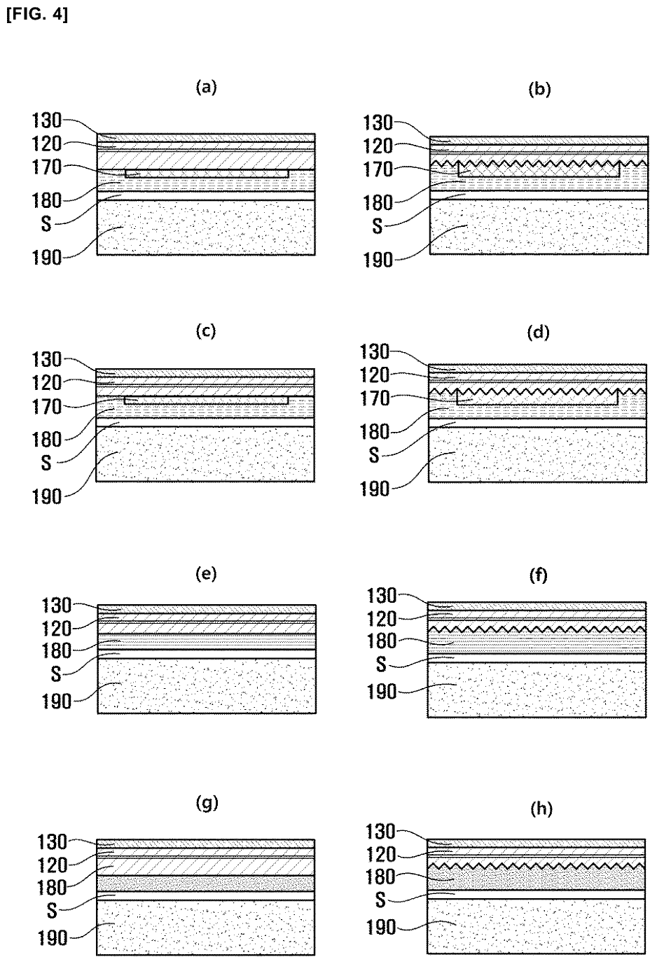

FIGS. 1 and 2 illustrate an overall process in which a chip-on-wafer is manufactured in accordance with a method (S100) of manufacturing a chip-on-wafer for a micro LED display according to a first embodiment of the present invention, FIG. 3 is a flowchart of the method (S100) of manufacturing a chip-on-wafer for a micro LED display according to the first embodiment of the present invention, and FIG. 4 illustrates various structures of chip-on-wafers manufactured in accordance with the method (S100) of manufacturing a chip-on-wafer for a micro LED display according to the first embodiment of the present invention.

As shown in FIGS. 1 to 3, in the method (S100) of manufacturing a chip-on-wafer for a micro LED display according to the first embodiment of the present invention, a chip-on-wafer is manufactured through a two-time wafer bonding method, and the method (S100) includes a growth operation S110, an electrode formation operation S120, an adhesion operation S130, an exposure operation S140, an etching operation S150, a bonding operation S160, and a removal operation S170.

The growth operation S110 is an operation of preparing an initial growth substrate 110 and epitaxially growing a semiconductor layer 120 on the initial growth substrate 110.

When the semiconductor layer 120 emits blue or green light, the initial growth substrate 110 may be provided as a sapphire (α-phase Al₂O₃) substrate that is optically transparent and has high temperature resistance, and allows 100% (theoretical) transmission of a laser beam (single-wavelength light) without absorption when a laser lift-off (LLO) process is used to remove the initial growth substrate 110. When a chemical lift-off (CLO) process is used to remove the initial growth substrate 110, the initial growth substrate 110 may be provided as a silicon (Si) substrate having a (111), (110), or (100) crystal plane that can be removed by wet etching.

Meanwhile, when the initial growth substrate 110 is provided as a sapphire substrate, it is preferable that the initial growth substrate 110 has a protrusion structure patterned regularly or irregularly in various dimensions (size and shape) at the microscale or nanoscale, in order to minimize crystal defects in a Group III nitride semiconductor thin film grown thereon (patterned sapphire substrate, PSS).

In addition, when the semiconductor layer 120 emits red light, the initial growth substrate 110 may be provided as a GaAs substrate that can be removed by wet etching through a chemical lift-off (CLO) process. Furthermore, when the semiconductor layer 120 emits red light through a high-quality InGaN active region 124 with a high In composition of 30% or more, the initial growth substrate 110 may be provided as a sapphire or Si substrate, as in the case in which the semiconductor layer 120 emits blue or green light.

The semiconductor layer 120 generates light and includes a third semiconductor region 123, a second semiconductor region 122, an active region 124, and a first semiconductor region 121.

In the present invention, the semiconductor layer 120 may emit blue, green, or red light, and when the semiconductor layer 120 emits blue or green light, binary, ternary, or quaternary compounds, such as InN, InGaN, GaN, AlGaN, AlN, or AlGaInN, which are Group III (Al, Ga, and In) nitride semiconductors among Group III-V compound semiconductors, can be epitaxially grown on the initial growth substrate 110 by being placed in appropriate positions and sequences.

In particular, in order to emit blue or green light, a high-quality InGaN Group III nitride semiconductor with a high In composition should preferentially be formed on top (the active region 124) of Group III nitride semiconductors composed of GaN, AlGaN, AlN, or AlGaInN, but the present invention is not limited thereto.

Further, in the present invention, when the semiconductor layer 120 emits red light, binary, ternary, and quaternary compounds such as InP, InGaP, GaP, AlInP, AlGaP, AlP, or AlGaInP, which are Group III (Al, Ga, and In) phosphide semiconductors among Group III-V compound semiconductors, may be epitaxially grown on the initial growth substrate 110 by being placed at appropriate positions and sequence.

In particular, in order to emit red light, a high-quality InGaP Group III phosphide semiconductor with a high In composition should preferentially be formed on top of Group III phosphide semiconductors composed of GaP, AlInP, AlGaP, AIP, or AlGaInP, but the present invention is not limited thereto, and for convenience of description, the following description will be based on Group III nitride semiconductors.

In addition, to further enhance the value of display panel products, along with the recent development of equipment and process technology, when emitting red light, a high-quality InGaN group III nitride semiconductor with a high In composition of 30% or more may be preferentially formed on top (the active region 124) of Group III nitride semiconductors composed of GaN, AlGaN, AlN, or AlGaInN, in addition to group III phosphide semiconductors. Specifically, when the active region 124 is composed of InₓGa₁₋ₓN, the active region emits blue light in a wavelength range of 450 nm to 470 nm when the indium composition, x, is 16% to 20%, emits green light in a wavelength range of 525 nm to 540 nm when the indium composition is 22% to 28%, and emits red light in a wavelength range of 625 nm to 635 nm when the indium composition is 30% to 35% (preferably 33%).

More specifically, in the growth operation S110, the third semiconductor region 123, which is an un-doped semiconductor region (e.g., uGaN, uInGaN, uAlGaN, or uAlGaInN), the second semiconductor region 122, which is an n-type semiconductor region (e.g., nGaN, nInGaN, nAlGaN, or nAlGaInN), a multi-quantum well (MQW) active region 124, and the first semiconductor region 121, which is a p-type semiconductor region (e.g., pGaN, pInGaN, pAlGaN, or pAlGaInN), may be epitaxially grown in sequence on the initial growth substrate 110, and the resulting structure may include multiple layers of Group III nitrides and typically have an overall thickness of approximately 5.0 to 8.0 μm, but the present invention is not limited thereto.

The third semiconductor region 123 is an un-doped semiconductor region, and specifically, the third semiconductor region 123 serves as a buffer region introduced prior to epitaxially growing the second semiconductor region 122, the active region 124, and the first semiconductor region 121 on the initial growth substrate 110, in order to relieve stress of the epitaxially grown second semiconductor region 122, active region 124, and first semiconductor region 121 and improve the thin-film quality.

The third semiconductor region 123 may include a nucleation layer (NL) and may typically be formed to have a thickness of 2.5 μm to 3 μm. In addition, when the initial growth substrate 110 is removed using a laser lift-off (LLO) technique, a sacrificial layer (SL) may be provided between the nucleation layer and the third semiconductor region 123, and the nucleation layer may function as the sacrificial layer.

The second semiconductor region 122 has n-type conductivity and is formed on the third semiconductor region 123. This second semiconductor region 122 may have a thickness of 2.0 to 2.5 μm, and a surface thereof may have nitrogen polarity (N-polarity).

The active region 124, which has a multi-quantum well structure and generates light through recombination of electrons and holes, is formed on the second semiconductor region 122. The active region 124 may be formed as multiple layers with a thickness of approximately 50 nm.

The first semiconductor region 121 has p-type conductivity and is formed on the active region 124. The first semiconductor region 121 may be formed as multiple layers with a thickness of 0.5 μm or less, and a top surface thereof may have gallium polarity (Ga-polarity).

That is, the active region 124 is interposed between the second semiconductor region 122 and the first semiconductor region 121, and generates light when electrons from the second semiconductor region 122, which is an n-type semiconductor region, and holes from the first semiconductor region 121, which is a p-type semiconductor region, recombine in the active region 124.

The electrode formation operation S120 is an operation of forming an ohmic contact electrode 130 on the semiconductor layer 120.

According to a conventional chip-on-wafer method, since the stacked structure of chips (including lateral chips, flip chips, and vertical chips) is completed using only the initial growth substrate 110, a p-type ohmic contact (p-ohmic contact) electrode must be formed in a back-end process. In this case, since the formation of the p-ohmic contact electrode 130 essentially requires heat treatment at a temperature of 450° C. or higher, there is an issue that the chip, in which a plurality of layers have already been stacked, may be damaged by the high temperature.

Accordingly, in the present invention, after the semiconductor layer 120 is grown in a state in which other layers are not yet stacked (i.e., before the structure of the chip is completed), the p-ohmic contact electrode 130 is formed through high-temperature heat treatment, and then the remaining necessary layers, such as a reflective layer 170, are stacked on one surface of the semiconductor layer 120, thereby fundamentally preventing damage to the chip having a stacked structure, which would be caused by the high-temperature heat treatment for forming the p-ohmic contact electrode 130.

More specifically, in the present invention, the ohmic contact electrode 130 is formed in contact with the first semiconductor region 121, which is a p-type semiconductor, and thus functions as a p-ohmic contact electrode, and since the present embodiment is applied to a vertical chip structure, the p-ohmic contact electrode 130 is formed of a transparent conductive material so that light from the lower side can be transmitted upward. In this case, the material for the ohmic contact electrode 130 may include NiO, PtO, PdO, AgO₂, Au, Rh₂O₃, RuO₂, In₂O₃, SnO₂, ZnO, IZO, ITO, IGZO, or the like.

Meanwhile, in the present invention, the p-ohmic contact electrode 130 may have a single-layer structure, and may also have a multi-layer structure in which the thin p-ohmic contact electrode 130 is first formed on a gallium-polarity (Ga-polarity) surface, and then a p-type electrode made of a material that is the same as or a different from the p-ohmic contact electrode 130 is formed thereon and electrically connected to the underlying p-ohmic contact electrode 130.

The adhesion operation S130 is an operation of bonding the ohmic contact electrode 130 to an intermediate temporary substrate 150 through an adhesive layer 140.

Here, the intermediate temporary substrate 150 preferably has a coefficient of thermal expansion (CTE) that is equal to or similar to those of the initial growth substrate 110 and the final support substrate 190. When a laser lift-off (LLO) process is used to remove the intermediate temporary substrate 150, the substrate may be provided as a sapphire (α-phase Al₂O₃) substrate or as glass whose CTE is controlled to differ from that of the final support substrate 190 by 2 ppm or less, both of which are optically transparent and have high temperature resistance, and allow 100% (theoretical) transmission of a laser beam (single-wavelength light) without absorption, and when a chemical lift-off (CLO) process is used to remove the intermediate temporary substrate 150, the substrate may be provided as an Si substrate having a (111), (110), or (100) crystal plane that can be removed by wet etching.

Further, in the present embodiment, the adhesive layer 140 may be formed of a metal or alloy, ceramic, or resin material. In particular, it is preferable that the adhesive layer 140 is preferentially formed of a material suitable for metallic bonding (eutectic bonding, diffusion bonding, direct bonding, and the like), and the adhesive layer 140 may include a metallic bonding material that is solderable at a temperature of 300° C. or lower, and may include materials such as In, Sn, Ga, Zn, Au, Ag, Cu, Pd, Ni, Ti, Cr, Al, or Si. In addition, the adhesive layer 140 may include ceramic materials that allow direct bonding at a temperature of 100° C. or lower, such as SiO₂, spin-on glass (SOG), flowable oxides (FOX), SiNx, Al₂O₃, AlN, SiCN, ITO, IZO, or ZnO, and may also include resin materials, such as epoxy, benzocyclobutene (BCB), or polyimide (PI), which are organic adhesives that allow indirect bonding at a temperature of 100° C. or lower.

Meanwhile, in the adhesion operation S130, after a sacrificial separation layer S is formed on the intermediate temporary substrate 150, the ohmic contact electrode 130 may be bonded to the sacrificial separation layer S through the adhesive layer 140. The sacrificial separation layer S is a layer that is sacrificed and separated during the removal of the intermediate temporary substrate 150, and the material thereof may vary depending on whether a laser lift-off (LLO) process or a chemical lift-off (CLO) process is used. Meanwhile, the sacrificial separation layer S may be positioned above or below the adhesive layer 140 depending on the purpose, and when the adhesive layer 140 performs the function of the sacrificial separation layer S, the sacrificial separation layer S may be omitted.

Further, in the adhesion operation S130, after a protective layer P is formed on the ohmic contact electrode 130, the protective layer P may be bonded to the intermediate temporary substrate 150 through the adhesive layer 140. The protective layer P serves to protect the device below the ohmic contact electrode 130 when the adhesive layer 140 is removed in a subsequent process. Representative materials for the protective layer P may include SiO₂, SiNx, AlN, or the like, but are not limited thereto, and various materials may be used depending on the method used to remove the adhesive layer 140 (for example, a SiO₂ protective layer P may be used when the adhesive layer 140 is removed using hydrochloric acid). Furthermore, the protective layer P may be omitted when the removal of the adhesive layer 140 does not affect the device.

Furthermore, in the adhesion operation S130, after the sacrificial separation layer S is formed on the intermediate temporary substrate 150 and the protective layer P is formed on the ohmic contact electrode 130, the protective layer P may be bonded to the sacrificial separation layer S through the adhesive layer 140.

The exposure operation S140 is an operation of exposing one surface of the semiconductor layer 120 by removing the initial growth substrate 110.

More specifically, in the exposure operation S140, the initial growth substrate 110 may be removed using a laser lift-off (LLO) process or a chemical lift-off (CLO) process, thereby exposing the third semiconductor region 123, which is an un-doped semiconductor region, to the outside.

The etching operation S150 is an operation of reducing the thickness of the semiconductor layer 120 by etching exposed one surface of the semiconductor layer 120.

According to the conventional chip-on-wafer method, since the stacked structure of chips (including lateral chips, flip chips, and vertical chips) is completed using only the initial growth substrate 110, the thickness of the un-doped semiconductor region (e.g., uGaN, uInGaN, uAlGaN, or uAlGaInN) or the n-type semiconductor region (e.g., nGaN, nInGaN, nAlGaN, or nAlGaInN) cannot be adjusted. As a result, it is difficult to manufacture high-quality and high-brightness micro-LEDs with a thickness of 5 μm or less, and the presence of such a thick un-doped semiconductor region leads to a reduction in light extraction efficiency.

Meanwhile, in the conventional chip-on-wafer method, the completed chip may be attached to a TFT glass or an interposer, and then the initial growth substrate 110 on the opposite side may be removed to expose the un-doped semiconductor region (e.g., uGaN, uInGaN, uAlGaN, or uAlGaInN). However, even when etching is attempted on the exposed un-doped semiconductor region, the completed chip may be damaged by the high temperatures and injected gases generated during the etching process.

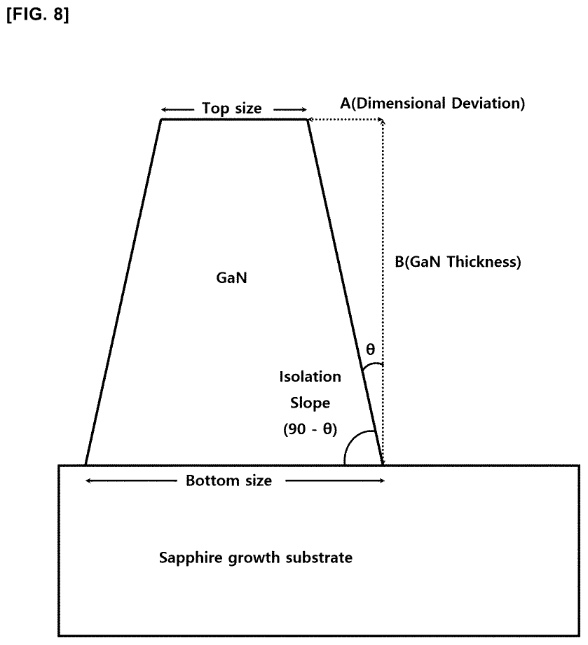

Meanwhile, FIG. 8 is a diagram for describing dimensional deviations that affect performance variations in the methods of manufacturing chip-on-wafers for micro LED displays according to the first and second embodiments of the present invention.

As shown in FIG. 8, the process of implementing a growth-completed epitaxial wafer into a device includes an isolation process that defines the size and shape of the chip, and in this process, the GaN semiconductor layer 120 is etched. In this process, photolithography may be used to etch the GaN semiconductor layer 120, in which a desired pattern is formed using a photoresist of a desired size and shape, followed by etching of the GaN semiconductor layer 120 through dry or wet etching based on the formed pattern.

In this case, during the etching process, a dimensional deviation A inevitably occurs between sizes of bottom and top surfaces of the semiconductor layer 120, and the dimensional deviation A is defined by the following equation.

$$A = tan θ \times B \qquad [ Equation 1 ]$$

(where B is the thickness of the semiconductor layer)

That is, since 0 and a thickness B of the semiconductor layer 120 are in a directly proportional relationship with the dimensional deviation A, a value of 0 or the thickness B of the semiconductor layer 120 must be reduced in order to minimize the dimensional deviation A of the chip. In other words, in the fabrication of ultra-small chips such as micro-LED chips, it is advantageous for an isolation slope to be closer to vertical and for the thickness of the semiconductor layer 120 to be smaller.

Furthermore, as the chip size decreases, a ratio of a side surface area increases, and accordingly, the smaller the chip size, the greater the impact of surface leakage and surface recombination occurring on the surface. To address this issue, either increasing the chip size or reducing the chip thickness may be considered, but since increasing the chip size is not meaningful, a solution is needed to reduce the chip thickness.

More specifically, in the case of a micro-LED chip having a top surface size in the range of 0.1 to 10 μm, assuming that the isolation slope is implemented at an angle between 80° and 89°, the required thickness of the semiconductor layer 120 for maintaining the dimensional deviation A within 10% is as shown in the following table. Meanwhile, as the isolation slope approaches 90°, the thickness of the semiconductor layer 120 may become greater, but it is practically difficult to achieve an isolation slope of 90°.

TABLE 1

| | Case 1 | Case 2 | Case 3 | Case 4 | Case 5 | Case 6 |
|---|---|---|---|---|---|---|
| Top size | 0.10 | 0.10 | 1.00 | 1.00 | 10.00 | 10.00 |
| (μm) | | | | | | |
| Bottom size | 0.11 | 0.11 | 1.10 | 1.10 | 11.00 | 11.00 |
| (μm) | | | | | | |
| Dimensional | 0.01 | 0.01 | 0.1 | 0.1 | 1 | 1 |
| deviation | | | | | | |
| (μm) | | | | | | |
| Isolation slope | 80 | 89 | 80 | 89 | 80 | 89 |
| (°) | | | | | | |
| θ (°) | 10 | 1 | 10 | 1 | 10 | 1 |
| tanθ | 0.18 | 0.02 | 0.18 | 0.02 | 0.18 | 0.02 |
| Required | 0.057 | 0.57 | 0.57 | 5.7 | 5.7 | 57.3 |
| thickness of | (Impossible to | | | | | (Thickness |
| semiconductor | implement) | | | | | reduction not |
| layer 120 | | | | | | required) |

As shown in the above table, assuming that the isolation slope is ideally implemented up to 89°, the required thickness of the semiconductor layer 120 to achieve the dimensional deviation A within 10% in a micro-LED chip having a top surface size in the range of 0.1 to 10 μm is found to be in the range of 0.57 to 5.7 μm. In addition, after performing the growth operation S110 to the exposure operation S140 of the present invention, it was confirmed through an actual prototype that the semiconductor layer 120 could be implemented with a thickness of 0.57 to 5.7 μm by etching and removing the third semiconductor region 123, which is an un-doped semiconductor region having a thickness of 2.5 to 3 μm, and partially etching the second semiconductor region 122, which is an n-type semiconductor region having a thickness of 2.0 to 2.5 μm, in the etching operation S150. That is, according to the present invention, after the ohmic contact electrode 130 on the semiconductor layer 120 is bonded to the intermediate temporary substrate 150 and the initial growth substrate 110 is removed in a state in which other layers have not been stacked (i.e., before the chip structure is completed), the thickness of the semiconductor layer 120 can be significantly reduced to 0.57 to 5.7 μm by etching the un-doped semiconductor region (uGaN) and the n-type semiconductor region (nGaN) of the semiconductor layer 120, thereby enabling the manufacture of high-quality, high-brightness chips for micro-LED displays. Accordingly, in the etching operation S150, the thickness of the semiconductor layer 120 can be reduced by etching and removing a portion or all of the third semiconductor region 123, which is an un-doped semiconductor region exposed by removing the growth substrate 110, and when the third semiconductor region 123 is removed, a portion of the second semiconductor region 122 may be additionally etched to a predetermined thickness, so that the thickness of the semiconductor layer 120 becomes 0.57 to 5.7 μm.

Meanwhile, when a buffer layer is provided below the third semiconductor region 123, the exposure operation S140 may expose one surface of the buffer layer, and in the etching operation S150, the buffer layer and the third semiconductor region 123 may be etched and removed, followed by etching the second semiconductor region 122 to a predetermined thickness.

The bonding operation S160 is an operation of bonding one surface of the semiconductor layer 120 to a final support substrate 190 through a bonding layer 180.

Here, the final support substrate 190 is a substrate that supports the chip structure obtained through the respective operations of the method (S100) of manufacturing a chip-on-wafer for a micro-LED display according to the first embodiment of the present invention. The final support substrate 190 may be provided, depending on the purpose, as a sapphire (α-phase Al₂O₃) substrate, a glass substrate having a controlled coefficient of thermal expansion (CTE), a silicon (Si) substrate, or the like.

Meanwhile, in the bonding operation S160, after the sacrificial separation layer S is formed on the final support substrate 190, one surface of the semiconductor layer 120 may be bonded to the sacrificial separation layer S. The sacrificial separation layer S is a layer that is sacrificed and separated during the removal of the final support substrate 190, and a material suitable for a laser lift-off (LLO) process may be used for this purpose. Meanwhile, the sacrificial separation layer S may be positioned above or below the bonding layer 180 depending on the purpose, and when the bonding layer 180 performs the function of the sacrificial separation layer S, the sacrificial separation layer S may be omitted.

The removal operation S170 is an operation of removing the intermediate temporary substrate 150 and the adhesive layer 140.

More specifically, in the removal operation S170, the intermediate temporary substrate 150 and the adhesive layer 140 are removed using a laser lift-off (LLO) process or a chemical lift-off (CLO) process, and when the sacrificial separation layer S and the protective layer P are formed, the sacrificial separation layer S and the protective layer P may also be removed together.

Meanwhile, as shown in FIG. 4, the chip-on-wafer for a micro-LED display chip according to the first embodiment of the present invention may have various structures.

First, as shown in FIGS. 4B, 4D, 4F, and 4H, in the etching operation S150 of the present invention, a surface texture pattern may be formed on the etched one surface of the semiconductor layer 120.

In addition, as shown in FIGS. 4A, 4B, 4C, and 4D, in the bonding operation S160 of the present invention, after a reflective layer 170 is formed on the etched one surface of the semiconductor layer 120, the bonding layer 180 is formed to surround the reflective layer 170, and the one surface of the semiconductor layer 120 on which the reflective layer 170 is formed may be bonded to a support substrate 190 or the sacrificial separation layer S through the bonding layer 180.

In this case, the reflective layer 170 may be formed of Ag, Al, Au, Pd, Pt, Ni, Mo, Cu, Cr, Ti, TiW, ITO, IZO, ZnO, TiN, a distributed Bragg reflector (DBR), an omni-directional reflector (ODR), or a combination thereof. As shown in FIGS. 4A and 4B, the reflective layer 170 may be in ohmic contact with the semiconductor layer 120, or, as shown in FIGS. 4C and 4D, the reflective layer 170 may not be in ohmic contact with the semiconductor layer 120.

In addition, as shown in FIGS. 4E, 4F, 4G, and 4H, in the bonding operation S160 of the present invention, without forming a separate reflective layer 170, the etched one surface of the semiconductor layer 120 may be bonded to the support substrate 190 or the sacrificial separation layer S through the bonding layer 180.

In this case, the bonding layer 180 may or may not be in ohmic contact with the semiconductor layer 120, and as shown in FIGS. 4E and 4F, when the bonding layer 180 is in ohmic contact with the semiconductor layer 120, the bonding layer 180 may be formed of a metal material and may include materials such as In, Sn, Ga, Zn, Au, Ag, Cu, Pd, Ni, Ti, Cr, Al, or Si, which are metallic bonding materials that can be soldered at temperatures of 300° C. or lower, and may also serve as a reflector.

In addition, as shown in FIGS. 4G and 4H, when the bonding layer 180 is not in ohmic contact with the semiconductor layer 120, the bonding layer 180 may include flowable oxides (FOx) such as SiO₂, SiNx, SiCN, AlN, Al₂O₃, spin-on-glass (SOG, liquid-phase SiO₂), or hydrogen silsesquioxane (HSQ), so that generated light can be transmitted therethrough, and in this case, the ohmic contact electrode 130 may be formed of a metallic material so as to reflect the generated light.

Hereinafter, a method (S200) of manufacturing a chip-on-wafer for a micro-LED display according to a second embodiment of the present invention will be described in detail with reference to the accompanying drawings.

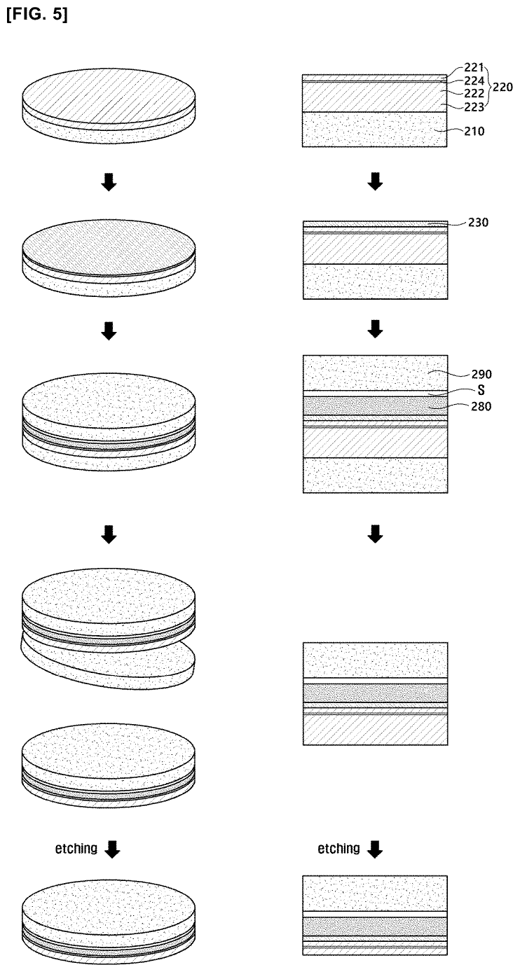

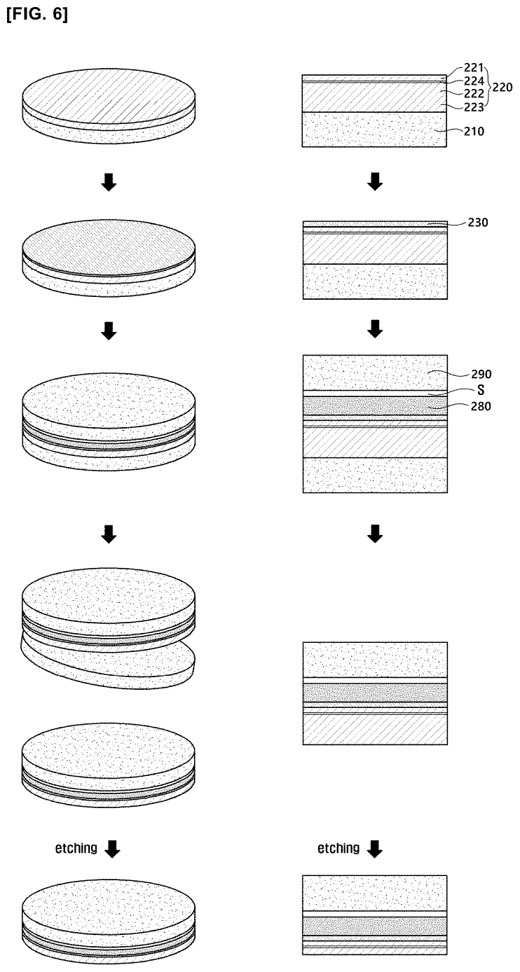

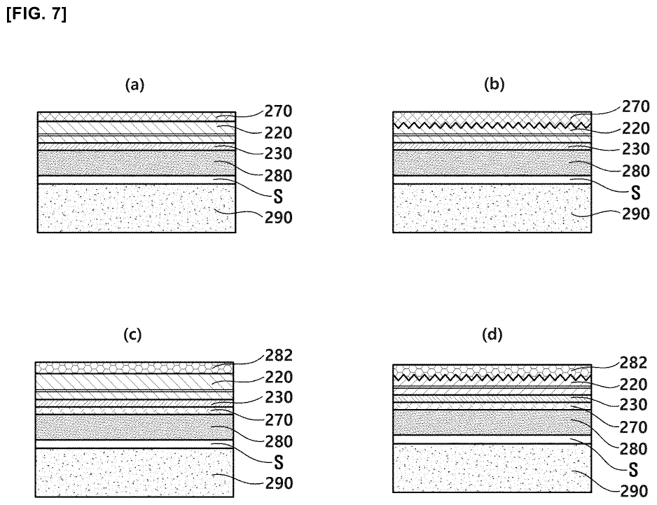

FIG. 5 illustrates an overall process in which a chip-on-wafer is manufactured in accordance with a method (S200) of manufacturing a chip-on-wafer for a micro-LED display according to a second embodiment of the present invention, FIG. 6 is a flowchart of the method (S200) of manufacturing a chip-on-wafer for a micro-LED display according to the second embodiment of the present invention, and FIG. 7 illustrates various structures of chip-on-wafers manufactured in accordance with the method (S200) of manufacturing a chip-on-wafer for a micro-LED display according to the second embodiment of the present invention.

As shown in FIGS. 5 to 6, in the method (S200) of manufacturing a chip-on-wafer for a micro-LED display according to the second embodiment of the present invention, a chip-on-wafer is manufactured through a one-time wafer bonding method, and the method (S200) includes a growth operation S210, an electrode formation operation S220, a bonding operation S230, an exposure operation S240, an etching operation S250, and a formation operation S260.

Here, details not described in the growth operation S210 and the electrode formation operation S220 are the same as those in the method (S100) of manufacturing a chip-on-wafer for a micro-LED display according to the first embodiment of the present invention described above, and thus redundant descriptions will be omitted.

The bonding operation S230 is an operation of bonding an ohmic contact electrode 230 to a final support substrate 290 through a bonding layer 280.

Here, the final support substrate 290 is a substrate that supports a chip structure obtained through respective operations of the method (S200) of manufacturing a chip-on-wafer for a micro-LED display according to the second embodiment of the present invention. The final support substrate 290 may be provided, like an initial growth substrate 210, as a sapphire (α-phase Al₂O₃) substrate, a glass substrate having a controlled coefficient of thermal expansion (CTE), a silicon (Si) substrate, or the like.

In addition, in the present embodiment, the bonding layer 280 may include flowable oxides (FOX) such as SiO₂, SiNx, SiCN, AlN, Al₂O₃, spin-on-glass (SOG, liquid-phase SiO₂), or hydrogen silsesquioxane (HSQ), so that the generated light can be transmitted therethrough.

Meanwhile, in the bonding operation S230, after a sacrificial separation layer S is formed on the final support substrate 290, the ohmic contact electrode 230 may be bonded to the sacrificial separation layer S. The sacrificial separation layer S is a layer that is sacrificed and separated during the removal of the final support substrate 290, and a material suitable for a laser lift-off (LLO) process may be used for this purpose. Meanwhile, the sacrificial separation layer S may be positioned above or below the bonding layer 280 depending on the purpose, and when the bonding layer 280 performs the function of the sacrificial separation layer S, the sacrificial separation layer S may be omitted.

The exposure operation S240 is an operation of exposing one surface of a semiconductor layer 220 by removing the initial growth substrate 210.

The etching operation S250 is an operation of reducing a thickness of the semiconductor layer 220 by etching the exposed one surface of the semiconductor layer 220.

Here, details not described in the exposure operation S240 and the etching operation S250 are the same as those in the method (S100) of manufacturing a chip-on-wafer for a micro-LED display according to the first embodiment of the present invention described above, and thus redundant descriptions will be omitted.

The formation operation S260 is an operation of forming a reflective layer 270 or a transmission layer 282 on the etched one surface of the semiconductor layer 220. The reflective layer 270 may be formed of Ag, Al, Au, Pd, Pt, Ni, Mo, Cu, Cr, Ti, TiW, ITO, IZO, ZnO, TiN, a distributed Bragg reflector (DBR), an omni-directional reflector (ODR), or a combination thereof. The transmission layer 282 is formed of a transparent conductive material so that light from the lower side can pass upward, and in this case, the material for the transmission layer 282 may include NiO, PtO, PdO, AgO₂, Au, Rh₂O₃, RuO₂, In₂O₃, SnO₂, ZnO, IZO, ITO, IGZO, or the like.

Meanwhile, as shown in FIG. 7, the chip-on-wafer for a micro-LED display chip according to the second embodiment of the present invention may have various structures.

First, as shown in FIGS. 7B and 7D, in the etching operation S250 of the present invention, a surface texture pattern may be formed on the etched one surface of the semiconductor layer 220.

In addition, as shown in FIGS. 7A and 7B, in the formation operation S260 of the present invention, the reflective layer 270 that reflects light generated on the etched one surface of the semiconductor layer 220 may be formed, and in this case, the reflective layer 270 may or may not be in ohmic contact with the semiconductor layer 220.

In addition, as shown in FIGS. 7C and 7D, in the formation operation S260 of the present invention, the transmission layer 282 that transmits light generated on the etched one surface of the semiconductor layer 220 may be formed, and in this case, in the electrode formation operation S220, the reflective layer 270 may additionally be formed on the ohmic contact electrode 230. Meanwhile, the transmission layer 282 may or may not be in ohmic contact with the semiconductor layer 220.

Although all the components constituting the embodiments of the present invention have been described as being combined into one or being operated in a combined state, the present invention is not essentially limited to the embodiments. That is, all the components may be selectively combined and operated as one or more components within the scope of the present invention.

Further, because the terms, such as “comprising,” “including,” or “having” may mean that the corresponding component may be included unless there is a specially contradictory description, it should be construed that another component is not extruded but may be further included. Unless defined otherwise, all terms used herein, including technical or scientific terms, have the same meanings as those generally understood by those skilled in the art to which the present invention pertains. The terms, such as the terms defined in dictionaries, which are generally used, should be construed to coincide with the context meanings of the related technologies, and are not construed as ideal or excessively formal meanings unless explicitly defined in the present invention.

In addition, the above description is a simple exemplification of the technical spirits of the present invention, and the present invention may be variously corrected and modified by those skilled in the art to which the present invention pertains without departing from the essential features of the present invention.

Accordingly, the embodiments disclosed in the present invention are not provided to limit the technical spirits of the embodiments of the present invention but provided to describe the present invention, and the scope of the technical spirits of the present invention is not limited by the embodiments. The scope of protection of the present invention should be construed by the attached claims, and all the technical spirits within the equivalent ranges fall within the scope of the present invention.

1. A method of manufacturing a chip-on-wafer for a micro-light-emitting diode (LED) display, the method comprising:
a growth operation of epitaxially growing a semiconductor layer on an initial growth substrate;
an electrode formation operation of forming an ohmic contact electrode on the semiconductor layer;
an adhesion operation of bonding the ohmic contact electrode to an intermediate temporary substrate through an adhesive layer;
an exposure operation of exposing one surface of the semiconductor layer by removing the initial growth substrate;
an etching operation of etching the exposed one surface of the semiconductor layer to reduce a thickness of the semiconductor layer;
a bonding operation of bonding the etched one surface of the semiconductor layer to a final support substrate; and
a removal operation of removing the intermediate temporary substrate and the adhesive layer.

2. The method of claim 1, wherein,
in the growth operation, a third semiconductor region, a second semiconductor region, an active region, and a first semiconductor region are epitaxially grown in sequence on the initial growth substrate,
in the etching operation, the third semiconductor region, which is exposed, is etched to reduce the thickness of the semiconductor layer, and
the third semiconductor region is an un-doped semiconductor region.

3. The method of claim 2, wherein
in the etching operation, the second semiconductor region is etched to reduce the thickness of the semiconductor layer, and
the second semiconductor region is an n-type semiconductor region.

4. A method of manufacturing a chip-on-wafer for a micro-light-emitting diode (LED) display, the method comprising:
a growth operation of epitaxially growing a semiconductor layer on an initial growth substrate;
an electrode formation operation of forming an ohmic contact electrode on the semiconductor layer;
a bonding operation of bonding the ohmic contact electrode to a final support substrate;
an exposure operation of exposing one surface of the semiconductor layer by removing the initial growth substrate; and
an etching operation of etching the exposed one surface of the semiconductor layer to reduce a thickness of the semiconductor layer.

5. The method of claim 4, wherein
in the growth operation, a third semiconductor region, a second semiconductor region, an active region, and a first semiconductor region are epitaxially grown in sequence on the initial growth substrate,
in the etching operation, the third semiconductor region, which is exposed, is etched to reduce the thickness of the semiconductor layer, and
the third semiconductor region is an un-doped semiconductor region.

6. The method of claim 5, wherein
in the etching operation, the second semiconductor region is etched to reduce the thickness of the semiconductor layer, and
the second semiconductor region is an n-type semiconductor region.
